(19) United States
(12) Patent Application Publication
(10) Pub. No.: US 2024/0094623 A1
(43) Pub. Date: Mar. 21, 2024

(54) ATTENUATED PHASE SHIFT MASK FOR TALBOT LITHOGRAPHY

(71) Applicant: META PLATFORMS, INC., Menlo Park, CA (US)

(72) Inventors: Cheng Xu, Kirkland, WA (US); Daniel Albert Corliss, Redmond, WA (US)

(21) Appl. No.: 17/899,263

(22) Filed: Aug. 30, 2022

(51) Int. Cl. G03F 1/32; G03F 7/20

(52) U.S. Cl. CPC G03F 1/32; G03F 7/70283

(57) ABSTRACT

A system for creating patterns on a wafer by using an attenuated phase shift mask with variable feature sizes and using Talbot lithography.

### TECHNOLOGICAL FIELD

Exemplary embodiments of this disclosure relate generally to methods or apparatuses for variable feature size using attenuated phase shift mask with Talbot lithography.

### BACKGROUND

Photolithography (also referred herein as lithography) is a method used in the fabrication of integrated circuits, such as solid-state memories or microprocessors. With the use of lithography, extremely small patterns (e.g., nanometers in size) may be created. Lithography methods may be used to create patterns on a substrate, such as a silicon wafer. Lithography may include the use of a photomask, in which the photomask may include an opaque pattern or semi-transparent pattern that may block the light from shining through the photomask while holes or opening spaces allow light to pass through in a defined pattern and exposure onto a photoresist or similar coating.

### BRIEF SUMMARY

Disclosed herein are methods, systems, and apparatus that may implement lithography for semiconductor fabrication, which may be based on the Talbot effect. Instead of using multiple masks, such as chromeless phase shift mask/apodization mask pair, a single attenuated phase shift mask may be used. The attenuated phase shift mask may have varied feature sizes embedded directly within the mask. In an example, a system may include a light source, a wafer, and an attenuated phase shift mask with variable feature sizes, wherein the attenuated phase shift mask is positioned between the light source and the wafer.

Advantages will be set forth in part in the description which follows or may be learned by practice. The advantages will be realized and attained by means of the elements and combinations particularly pointed out in the appended claims. It is to be understood that both the foregoing general description and the following detailed description are exemplary and explanatory only and are not restrictive, as claimed.

### BRIEF DESCRIPTION OF THE DRAWINGS

FIG. 1A illustrates an exemplary system for Talbot lithography using a pairing of chromeless phase shift lithography mask and apodization mask.

FIG. 1B illustrates an exemplary method associated with system of FIG. 1A.

FIG. 2A illustrates an exemplary system for Talbot lithography using attenuated phase shift mask.

FIG. 2B illustrates an exemplary method associated with system of FIG. 2A.

FIG. 3 illustrates an exemplary block diagram of a device that may be used to implement the disclosed subject matter.

The figures depict various embodiments for purposes of illustration only. One skilled in the art will readily recognize from the following discussion that alternative embodiments of the structures and methods illustrated herein may be employed without departing from the principles described herein.

### DETAILED DESCRIPTION

Some embodiments of the present invention will now be described more fully hereinafter with reference to the accompanying drawings, in which some, but not all embodiments of the invention are shown. Indeed, various embodiments of the invention may be embodied in many different forms and should not be construed as limited to the embodiments set forth herein. Like reference numerals refer to like elements throughout.

It is to be understood that the methods and systems described herein are not limited to specific methods, specific components, or to particular implementations. It is also to be understood that the terminology used herein is for the purpose of describing particular embodiments only and is not intended to be limiting.

In photolithography, an incident light system may include collimated light that may travel through one or more photolithography masks that are along the light pathway. The masks may carry some geometrical information (e.g., features) onto a substrate (e.g., semiconductor wafer) when exposed. Feature sizes, which may be variable, may be determined when the mask is manufactured. The wafer may photoresist to record what is on the mask onto the substrate.

Talbot lithography, which is also referred to as displacement Talbot lithography (DTL), is a high-resolution photolithography technique that may be used to produce periodic structures without the need for complex and expensive projection optics. The Talbot effect, which is also referred to as self-imaging or lens-less imaging, relates to a phenomenon manifested by a periodic repetition of planar field distributions in certain types of wave fields. With DTL, by integrating the diffraction field transmitted by a grating mask over the distance of one Talbot period, an effective image that is independent of the distance from the mask may be obtained. In this way, high-resolution periodic patterns may be printed without a depth-of-field limitation.

Conventional DTL uses a chromeless phase shift mask and an apodization mask concurrently to create images with differential dosing in order to achieve variable feature (e.g., pattern) sizes. A chromeless phase shift mask alone has a fixed feature dimension and varying the feature dimension may result in loss of image contrast and bad imaging at the wafer level. Therefore, an apodization mask is concurrently used to create varied intensity of light (dose) incident on the chromeless phase shift mask. The combination of the chromeless phase shift mask and apodization mask create wafer features of varied dimensions. Differential dosing is sensitive to image fidelity failure as the dose may be increased or decreased from a nominal center dose. The image fidelity failures (e.g., line edge roughness and increased sensitivity to size variation) limit the usable range of feature sizes. With regard to image fidelity failure, in addition to line edge roughness, there may be unintended gaps/breaks along the length of a pattern in photoresist, or bridge defects between adjacent patterns, or variations in sidewall angles of the pattern. The conventional chromeless phase shift mask/apodization mask pair may be limited to changing feature sizes by changing doses.

The disclosed attenuated phase shift mask may replace the conventional DTL implementations. The attenuated phase shift mask features may have varied feature sizes embedded directly into the mask. The feature sizes may be exposed at an optimal dose. The result may be an increased range of feature sizes and constant image fidelity across the range. Adjustments may be made to the printed range by adjusting the dose, while maintaining image fidelity. There is a process window of usable dose range for lithography processes (e.g., photoresist). The attenuated phase shift mask may be optimized to operate at the optimal setting within a process window. For this dose (and a range of doses around it) the pattern fidelity may be maintained throughout the range of intended varied feature sizes.

The apodization mask design is defined to support a range of printed feature sizes. Changing the dose by itself may not provide the intended change in feature sizes, as this is not a linear relationship. The non-linearity of the relationship requires that a new apodization mask design may be required to shift the range of desired feature sizes. Alternatively for attenuated phase shift mask, there may be a near linear relationship between dose and shifting range of printed feature sizes. This may work for the usable dose range, which may be informed by the consideration of empirical data or modeled data.

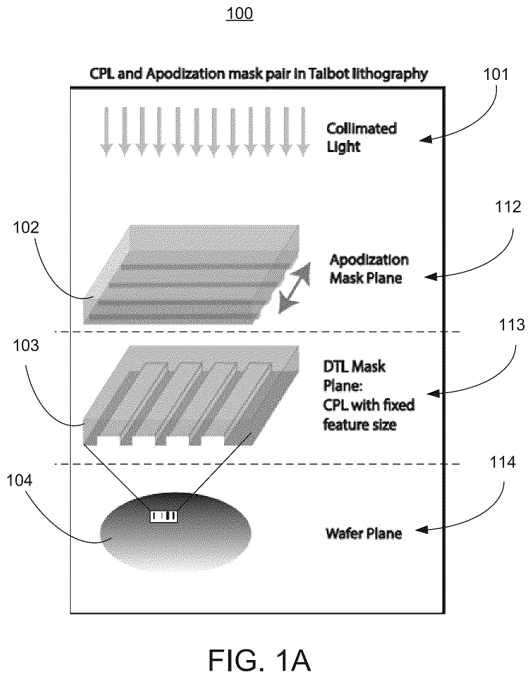

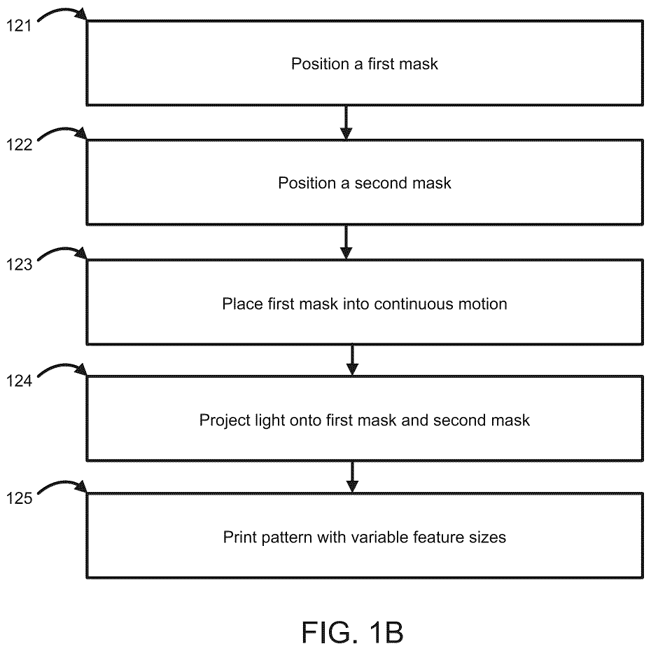

FIG. 1A illustrates an exemplary system 100 for Talbot lithography (referred herein as DTL) using a chromeless phase shift lithography (CPL) mask 103 and apodization mask 102 for variable feature sizes. DTL may allow for increased resolution, but a two-mask system is used for variable feature sizes. As shown, system 100 may include a light source 101 (e.g., a collimated light), apodization mask 102 within apodization mask plane 112, DTL-CPL mask 103 within DTL mask plane 113, or wafer 104 within wafer plane 114.

To implement variable feature sizes in this DTL configuration, apodization mask 102 may move constantly while DTL-CPL mask 103 is of a fixed feature size. With reference to photolithography, apodization is an optical filtering technique for changing the shape of an optical transmission and may be used to improve the focus. Because system 100 uses chromeless phase shift mask 103 the image fidelity has limited range to work with, so without apodization and just DTL-CPL mask 103 alone, the system 100 may be ineffective to obtain a variable duty cycle range. Again, conventionally, DTL-CPL mask 103 is usually paired with another mask, such as apodization mask 102, to create variable feature sizes.

DTL-CPL mask 103 by itself (without apodization mask 102) may only form a good image for a very small range of feature sizes. A good image may be defined by feature size meeting a specified target, acceptable line edge roughness (LER) and sidewall angle, no or within a threshold pattern failure or fidelity defects (e.g., breaks or opens in a feature or bridges between features). Therefore, a pairing of apodization mask 102 with DTL-CPL mask 103 may be used to obtain a more robust range of variable feature sizes. Apodization mask plane 102 has a variable feature size, while DTL-CPL mask 103 has a fixed feature size.

FIG. 1B illustrates an exemplary method associated with system 100. At step 121, a first mask (e.g., apodization mask 102) may be positioned between light source 101 and wafer 104. The first mask including variable feature sizes. At step 122, a second mask (e.g., DTL-CPL mask 103) may be positioned between apodization mask 102 and wafer 104. The second mask being of a fixed feature size. For apodization mask 102 and DTL-CPL mask 103 there may be a fixed orientation with respect to each other. In an example, as shown in FIG. 1A, in order to draw a straight line, the apodization features or the apodization mask movement may be orthogonal to the orientation of the chromeless mask features.

At step 123, place apodization mask 102 (e.g., the first mask) in continuous motion, such as when light is shined through apodization mask 102. During this light exposure apodization mask 102 may move constantly to create some variable feature sizes. Apodization mask 102 may move with a certain speed in a certain direction with respect to DTL-CPL mask 103, for example. After the exposure, apodization mask 102 may stop moving and return to its original location.

At step 124, light (e.g., collimated light) may be projected from light source 101 onto and through the first mask and second mask. At step 125, based on step 124, pattern may be printed onto wafer 104 that includes variable feature sizes. The aforementioned step 121-step 125 may be used to realize the variable feature sizes using DTL with CPL mask.

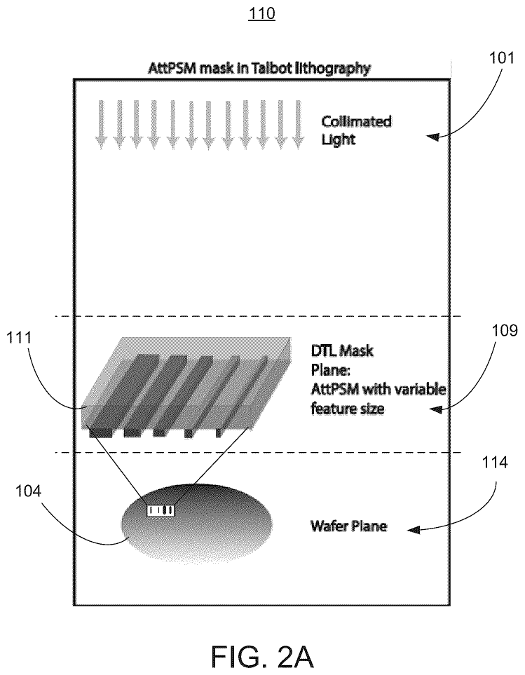

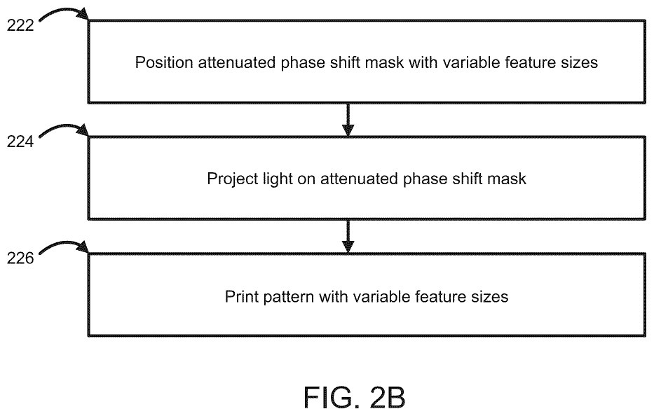

FIG. 2A illustrates an exemplary system 110 for DTL using attenuated phase shift mask 111. As shown, system 110 may include wafer plane 104, collimated light source 101, and attenuated phase shift mask 111 for variable feature sizes while using DTL. Attenuated phase shift mask 111 may be within DTL mask plane 109. An attenuated phase shift mask in photolithography may be comprised of a quartz substrate (e.g., 100% transparent at wavelength) and an attenuating layer of molybdenum silicide (MoSi) (e.g., approximately 6% transmissive at wavelength and other % transmissives are also possible). The mask features may be defined by openings in the attenuating layer. A combination of the light transmitted through the quartz area or the attenuated area may generate a phase shifted image.

In comparison to system 100 of FIG. 1A (or similar systems), system 110 may achieve comparable pattern formation capability without the use of apodization mask 102 or other masks. Because of the nature of attenuated phase shift mask 111, variable feature sets may be created with just one mask without sacrificing image fidelity. Although chromeless phase shift masks and attenuated phase shift masks are both types of phase shift masks, it has been discovered, based on experimentation, that an attenuated phase shift mask-based system does not need an additional mask for variable feature sizes for comparable pattern formation capability with conventional DTL based systems. In addition, attenuated phase shift mask 111 may be motionless.

FIG. 2B illustrates an exemplary method associated with system 110. At step 131, attenuated phase shift mask 111 may be positioned between light source 101 and wafer 104. The attenuated phase shift mask 111 has variable feature sizes.

At step 132, light (e.g., collimated light) may be projected from light source 101 onto and through attenuated phase shift mask 111. At step 133, based on step 132, print variable features sizes onto wafer 104. The disclosed system 110 may allow for the variable feature size to be realized in one print, rather than multiple prints as in conventional systems. During the fabrication of the mask, the features sizes are recorded inside the mask itself. Therefore, light shines through attenuated phase shift mask 111 and the variable feature sizes are recorded. The aforementioned step 131-step 133 may be used to realize the variable feature sizes. The varied feature sizes may be exposed at a predetermined dose. This may result in an increased range of feature sizes and constant image fidelity across the range. Additionally, adjustments can be made to the printed range by adjusting the dose, while maintaining image fidelity.

To obtain variable feature sizes there is a need for good imaging information. For a feature mask, there is corresponding limited range in which printing is visible on wafer 104. With DTL-CPL it is difficult to change the size of the features (e.g., larger or smaller). If a change in size is attempted, then the images are of poor quality, unless an apodization mask 102 is used. Poor quality may be associated with feature size not meeting a specified target, LER not meeting a specified target, sidewall angle not meeting a specified target, or emergence of pattern fidelity defects as disclosed. Targets may be defined by predetermined integrated design or process requirements.

So, this phenomenon may happen when the pattern that is planned to print becomes small. As disclosed, attenuated phase shift mask 111 may be used without apodization mask 102 and may have comparable resolution as a pairing of DTL-CPL mask 103 and apodization mask 102. The optical formation mechanism for these two types of masks is different. The varied feature sizes may be exposed at a predetermined dose, which may result in an increased range of feature sizes and constant image fidelity across the range. Additionally, adjustments may be made to the printed range by adjusting the dose, while maintaining image fidelity. A technical effect of attenuated phase shift mask may be realized for fixed feature sizes not of equal feature/space pairings or for designs where a range of a range of sizes is required.

As a result of the conventional method with DTL-CPL mask 103, the intensity (e.g., dose) incident on the mask may be only optimal for a portion of the imageable range of varied feature sizes. This may be due to the extremes of varied feature sizes being in an under-dosed or over-dosed regime. Photoresist and subsequent support processes are more susceptible to accelerated negative impact to process stability in these regimes. As such, the feature sizes, LER, or pattern fidelity failures vary more greatly.

For an attenuated phase shift mask, the full range of features may be printed at the optimal dose, with good pattern fidelity. This may provide an opportunity to realize increased range of good feature sizes at the same time.

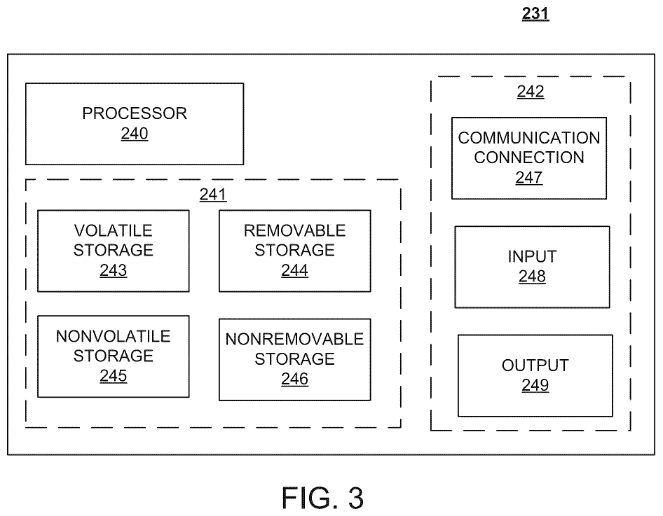

FIG. 3 is an exemplary block diagram of a device (e.g., apparatus) that may be used to implement the disclosed systems (e.g., system 110). In an example, apparatus 231 may include hardware or a combination of hardware and software. The functionality to facilitate telecommunications via a telecommunications network may reside in one or combination of network devices (e.g., apparatuses 231). Apparatus 231 may represent or perform functionality of an appropriate apparatus 231, such as a component or various components of a wireless network, a processor, a server, a gateway, a node, a gaming device, photolithography associated machinery, or the like, or any appropriate combination thereof. It is emphasized that the block diagram depicted in FIG. 3 is exemplary and not intended to imply a limitation to a specific implementation or configuration. Thus, apparatus 231 may be implemented in a single device or multiple devices (e.g., single server or multiple servers, single gateway or multiple gateways, single controller or multiple controllers). Multiple network entities may be distributed or centrally located. Multiple network entities may communicate wirelessly, via hard wire, or any appropriate combination thereof.

Apparatus 231 may comprise a processor 240 and a memory 241 coupled to processor 240. Memory 241 may contain executable instructions that, when executed by processor 240, cause processor 240 to effectuate operations.

In addition to processor 240 and memory 241, apparatus 231 may include an input/output system 242. Processor 240, memory 241, and input/output system 242 may be coupled together (coupling not shown in FIG. 3) to allow communications between them. Each portion of apparatus 231 may comprise circuitry for performing functions associated with each respective portion. Thus, each portion may comprise hardware, or a combination of hardware and software. Input/output system 242 may be capable of receiving or providing information from or to a communications device or other network entities configured for telecommunications. For example, input/output system 242 may include a wireless communications (e.g., Wi-Fi or 5G) card. Input/output system 242 may be capable of receiving or sending video information, audio information, control information, image information, data, or any combination thereof. Input/output system 242 may be capable of transferring information with apparatus 231. In various configurations, input/output system 242 may receive or provide information via any appropriate means, such as, for example, optical means (optical light source, such as laser, light emitting diode, etc.), electromagnetic means (e.g., radio frequency (RF), Wi-Fi, Bluetooth), acoustic means (e.g., speaker, microphone, ultrasonic receiver, ultrasonic transmitter), or a combination thereof. In an example configuration, input/output system 242 may comprise a Wi-Fi finder, a two-way GPS chipset or equivalent, or the like, or a combination thereof.

Input/output system 242 of apparatus 231 also may include a communication connection 247 that allows apparatus 231 to communicate with other devices, network entities, or the like. Communication connection 247 may comprise communication media. Communication media typically embody computer-readable instructions, data structures, program modules or other data in a modulated data signal such as a carrier wave or other transport mechanism and includes any information delivery media. By way of example, and not limitation, communication media may include wired media such as a wired network or direct-wired connection, or wireless media such as acoustic, RF, infrared, or other wireless media. The term computer-readable media as used herein includes both storage media and communication media. Input/output system 242 also may include an input device 248 such as keyboard, mouse, pen, voice input device, or touch input device. Input/output system 242 may also include an output device 249, such as a display, speakers, or a printer.

Processor 240 may be capable of performing functions associated with telecommunications, such as functions for processing broadcast messages, as described herein. For example, processor 240 may be capable of, in conjunction with any other portion of apparatus 231, determining a type of broadcast message and acting according to the broadcast message type or content, as described herein.

Memory 241 of apparatus 231 may comprise a storage medium having a concrete, tangible, physical structure. As is known, a signal does not have a concrete, tangible, physical structure. Memory 241, as well as any computer-readable storage medium described herein, is not to be construed as a signal. Memory 241, as well as any computer-readable storage medium described herein, is not to be construed as a transient signal. Memory 241, as well as any computer-readable storage medium described herein, is not to be construed as a propagating signal. Memory 241, as well as any computer-readable storage medium described herein, is to be construed as an article of manufacture.

Herein, a computer-readable storage medium or media may include one or more semiconductor-based or other integrated circuits (ICs) (such, as for example, field-programmable gate arrays (FPGAs) or application-specific ICs (ASICs)), hard disk drives (HDDs), hybrid hard drives (HHDs), optical discs, optical disc drives (ODDs), magneto-optical discs, magneto-optical drives, floppy diskettes, floppy disk drives (FDDs), magnetic tapes, solid-state drives (SSDs), RAM-drives, SECURE DIGITAL cards or drives, any other suitable computer-readable non-transitory storage media, or any suitable combination of two or more of these, where appropriate. A computer-readable storage medium may be volatile, non-volatile, or a combination of volatile and non-volatile, where appropriate.

Memory 241 may store any information utilized in conjunction with telecommunications. Depending upon the exact configuration or type of processor, memory 241 may include a volatile storage 243 (such as some types of RAM), a nonvolatile storage 245 (such as ROM, flash memory), or a combination thereof. Memory 241 may include additional storage (e.g., a removable storage 244 or a non-removable storage 246) including, for example, tape, flash memory, smart cards, CD-ROM, DVD, or other optical storage, magnetic cassettes, magnetic tape, magnetic disk storage or other magnetic storage devices, USB-compatible memory, or any other medium that may be used to store information and that may be accessed by apparatus 231. Memory 241 may comprise executable instructions that, when executed by processor 240, cause processor 240 to effectuate operations to map signal strengths in an area of interest.

While the disclosed systems have been described in connection with the various examples of the various figures, it is to be understood that other similar implementations may be used or modifications and additions may be made to the described examples of a nanophotonic crack stop system without deviating therefrom. For example, one skilled in the art will recognize that a nanophotonic crack stop system as described in the instant application may apply to any environment, whether wired or wireless, and may be applied to any number of such devices connected via a communications network and interacting across the network. Therefore, the disclosed systems as described herein should not be limited to any single example, but rather should be construed in breadth and scope in accordance with the appended claims.

In describing preferred methods, systems, or apparatuses of the subject matter of the present disclosure—nanophotonic crack stop—as illustrated in the Figures, specific terminology is employed for the sake of clarity. The claimed subject matter, however, is not intended to be limited to the specific terminology so selected.

Herein, “or” is inclusive and not exclusive, unless expressly indicated otherwise or indicated otherwise by context. Therefore, herein, “A or B” means “A, B, or both,” unless expressly indicated otherwise or indicated otherwise by context. Moreover, “and” is both joint and several, unless expressly indicated otherwise or indicated otherwise by context. Therefore, herein, “A and B” means “A and B, jointly or severally,” unless expressly indicated otherwise or indicated otherwise by context.

Also, as used in the specification including the appended claims, the singular forms “a,” “an,” and “the” include the plural, and reference to a particular numerical value includes at least that particular value, unless the context clearly dictates otherwise. The term “plurality”, as used herein, means more than one. When a range of values is expressed, another embodiment includes from the one particular value and/or to the other particular value. Similarly, when values are expressed as approximations, by use of the antecedent “about,” it will be understood that the particular value forms another embodiment. All ranges are inclusive and combinable. It is to be understood that the terminology used herein is for the purpose of describing particular aspects only and is not intended to be limiting.

This written description uses examples to enable any person skilled in the art to practice the claimed subject matter, including making and using any devices or systems and performing any incorporated methods. Other variations of the examples are contemplated herein. It is to be appreciated that certain features of the disclosed subject matter which are, for clarity, described herein in the context of separate embodiments, may also be provided in combination in a single embodiment. Conversely, various features of the disclosed subject matter that are, for brevity, described in the context of a single embodiment, may also be provided separately or in any sub-combination. Further, any reference to values stated in ranges includes each and every value within that range. Any documents cited herein are incorporated herein by reference in their entireties for any and all purposes.

The scope of this disclosure encompasses all changes, substitutions, variations, alterations, and modifications to the example embodiments described or illustrated herein that a person having ordinary skill in the art would comprehend. The scope of this disclosure is not limited to the example embodiments described or illustrated herein. Moreover, although this disclosure describes and illustrates respective embodiments herein as including particular components, elements, feature, functions, operations, or steps, any of these embodiments may include any combination or permutation of any of the components, elements, features, functions, operations, or steps described or illustrated anywhere herein that a person having ordinary skill in the art would comprehend. Furthermore, reference in the appended claims to an apparatus or system or a component of an apparatus or system being adapted to, arranged to, capable of, configured to, enabled to, operable to, or operative to perform a particular function encompasses that apparatus, system, component, whether or not it or that particular function is activated, turned on, or unlocked, as long as that apparatus, system, or component is so adapted, arranged, capable, configured, enabled, operable, or operative. Additionally, although this disclosure describes or illustrates particular embodiments as providing particular advantages, particular embodiments may provide none, some, or all of these advantages.

Methods, systems, and apparatuses, among other things, as described herein may provide for using attenuated phase shift mask for printing variable feature sizes, as disclosed herein. A system may include a light source, a wafer, and an attenuated phase shift mask with variable feature sizes, wherein the attenuated phase shift mask is positioned between the light source and the wafer. The attenuated phase shift mask may be associated with Talbot lithography. The light source may project collimated light. The wafer may include photoresist material that exposes a pattern associated with the attenuated phase shift mask. A wafer may include a pattern, in which the pattern may be associated with an attenuated phase shift mask with variable feature sizes, wherein the attenuated phase shift mask incorporates Talbot lithography. The wafer may include photoresist material that the pattern which is associated with the attenuated phase shift mask. A phase shift mask may include variable feature sizes, wherein the phase shift mask is an attenuated phase shift mask and may incorporate Talbot lithography. A method may include positioning an attenuated phase shift mask between a light source and a wafer; projecting a light from the light source onto the attenuated phase shift mask; and obtaining a pattern on the wafer, based on the light and the attenuated phase shift mask. The method may be implemented using computing devices, such as robots, servers, or the like. All combinations in this paragraph and the previous paragraphs (including the removal or addition of steps or components) are contemplated in a manner that is consistent with the other portions of the detailed description.

What is claimed:

1. A system for creating variable feature sizes on a wafer, the system comprising:
a light source;
a wafer; and
an attenuated phase shift mask with variable feature sizes, wherein the attenuated phase shift mask is positioned between the light source and the wafer.

2. The system of claim 1, wherein the attenuated phase shift mask is associated with Talbot lithography.

3. The system of claim 1, wherein the light source projects collimated light.

4. The system of claim 1, wherein the wafer comprises photoresist material that exposes a pattern associated with the attenuated phase shift mask.

5. A wafer comprising a pattern, the pattern associated with an attenuated phase shift mask with variable feature sizes, wherein the attenuated phase shift mask incorporates Talbot lithography.

6. The wafer of claim 5, wherein the wafer comprises photoresist material that incorporates the pattern which is associated with the attenuated phase shift mask.

7. A method comprising:
positioning an attenuated phase shift mask between a light source and a wafer;
projecting a light from the light source onto the attenuated phase shift mask; and
obtaining a pattern on the wafer, based on the light and the attenuated phase shift mask.

8. The method of claim 7, wherein the attenuated phase shift mask is associated with Talbot lithography.

9. The method of claim 7, wherein the attenuated phase shift mask has variable feature sizes and is associated with Talbot lithography.

10. The method of claim 7, wherein the wafer comprises photoresist material that incorporates the pattern which is associated with the attenuated phase shift mask.
